(19) United States
(12) Patent Application Publication
(10) Pub. No.: US 2011/0294076 A1
(43) Pub. Date: Dec. 1, 2011

(54) METHOD FOR MAKING PATTERNED ROLLER

(75) Inventor: CHIA-LING HSU, Tu-Cheng (TW)

(73) Assignee: HON HAI PRECISION INDUSTRY CO., LTD., Tu-Cheng (TW)

(21) Appl. No.: 12/881,151

(22) Filed: Sep. 13, 2010

(30) Foreign Application Priority Data
May 26, 2010 (TW) 99116758

(51) Int. Cl. G03F 7/20

(52) U.S. Cl. 430/325

(57) ABSTRACT

A method for making a patterned roller includes: forming a dry film photoresist layer on an outer surface of a to-be-patterned roller; exposing the dry film photoresist layer to an exposure machine using a photomask; developing the dry film photoresist layer to expose a plurality of portions of the outer surface of the to-be-patterned roller; sandblasting the exposed portions of the outer surface of the to-be-patterned roller to define a pattern in the outer surface of the to-be-patterned roller; and removing the remaining dry film photoresist layer to obtain a patterned roller.

### BACKGROUND

1. Technical Field

The present disclosure relates to methods for making patterned rollers.

2. Description of Related Art

In a roll-to-roll process, a patterned roller is used for patterning a roll of flexible foil. Methods for making such patterned roller typically include a direct laser writing method, and a mechanical carving method.

In the direct laser writing method, waste from a to-be-patterned (TBP) roller may contaminate other portions of the TBP roller. Furthermore, if a copper TBP roller is used, an electroplating process should be performed before laser writing.

In the mechanical carving method, a carving or etching tool, such as a diamond needle is used. However, when the diamond needle is used, patterns can only be formed on the patterned roller with dots, and life of the tool is relatively short.

Therefore, a method for making a patterned roller, which can overcome the above-mentioned problems, is needed.

### BRIEF DESCRIPTION OF THE DRAWINGS

FIG. 1 is a flow chart of a method for making a patterned roller, according to an exemplary embodiment.

FIG. 2 to FIG. 5 are schematic views of successive stages of the method for making the patterned roller of FIG. 1.

### DETAILED DESCRIPTION

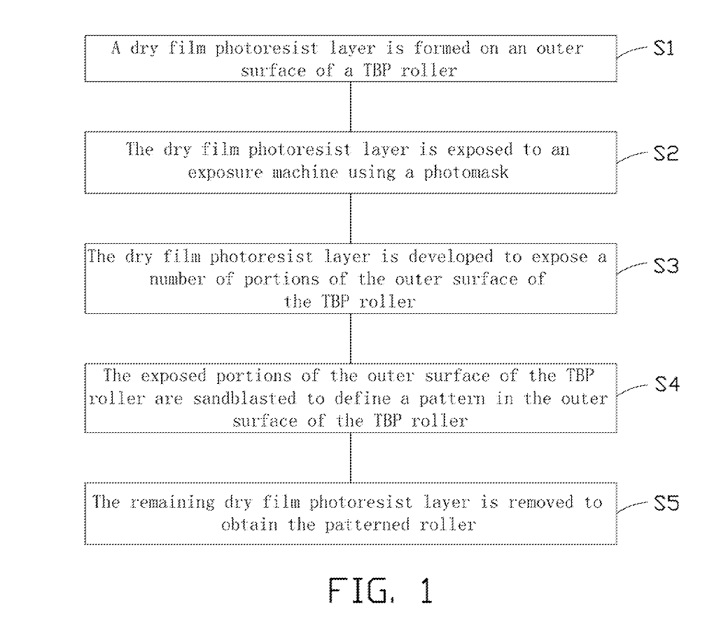

Referring to FIGS. 1 to 5, a method for making a patterned roller 100, according to an exemplary embodiment, includes the following steps S1 through S5. Step S1: a dry film photoresist layer 20 is formed on an outer surface of a TBP roller 10. Step S2: the dry film photoresist layer 20 is exposed to an exposure machine 30 using a photomask 40. Step S3: the dry film photoresist layer 20 is developed to expose a number of portions of the outer surface of the TBP roller 10. Step S4: the exposed portions of the outer surface of the TBP roller 10 are sandblasted to define a pattern in the outer surface of the TBP roller 10. Step S5: the remaining dry film photoresist layer 20 is removed to obtain the patterned roller 100.

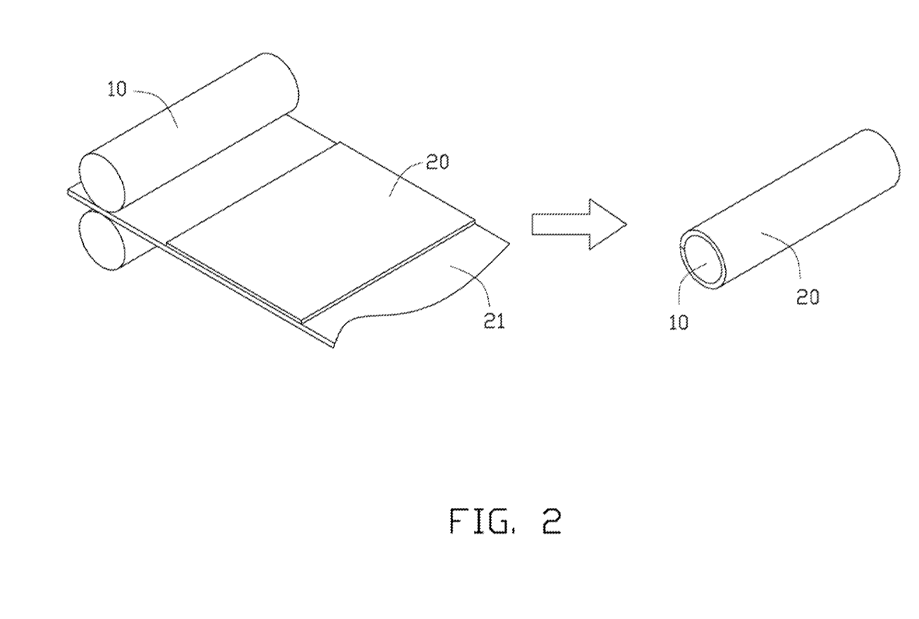

Referring to FIG. 2, in step S1, the TBP roller 10 is a cylindrical core and is mounted on a roll-to-roll machine. The dry film photoresist layer 20 is formed on a surface of a foil 21. The dry film photoresist layer 20 is transferred to the outer surface of the TBP roller 10 when the TBP roller 10 rolls on the dry film photoresist layer 20.

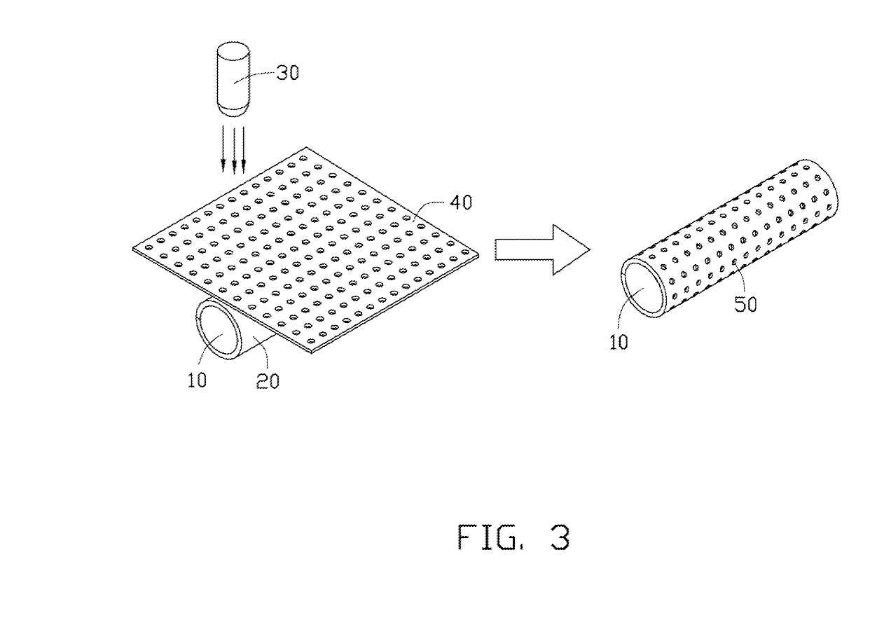

Referring to FIG. 3, in step S2, the exposure machine 30 is used. The exposure machine 30 and the TBP roller 10 with the dry film photoresist layer 20 are positioned at opposite sides of the photomask 40. After exposure and development, the dry film photoresist layer 20 is in a first pattern 50 on the TBP roller 10. In this embodiment, the first pattern 50 includes a number of through holes. Therefore, portions of the outer surface of the TBP roller 10 are exposed corresponding to the first pattern 50. In other embodiments, the first pattern 50 can be changed conveniently by using different photomasks. Furthermore, precision of the first pattern 50 can be improved if a photomask having a high precision is used.

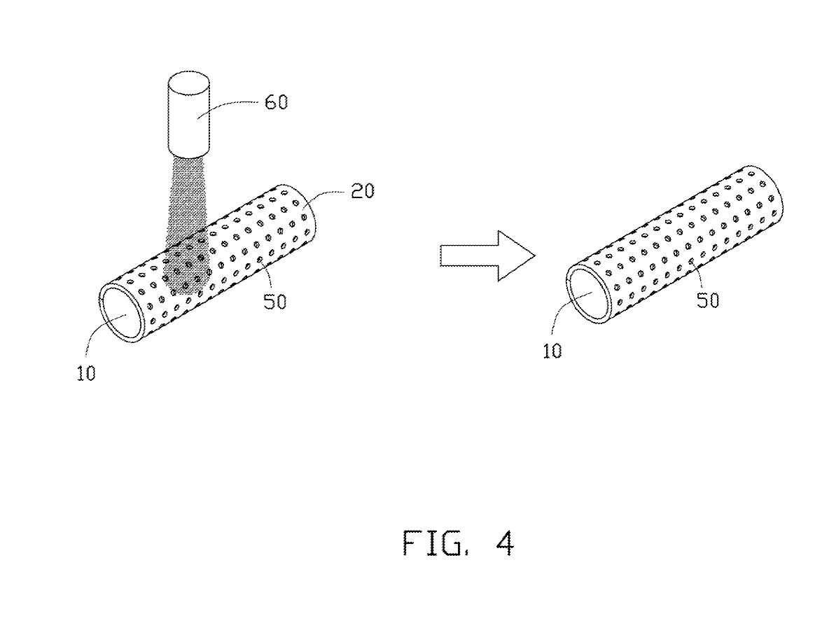

Referring to FIG. 4, in the step S4, the exposed portions of the outer surface of the TBP roller 10 are sandblasted by a sandblasting machine 60 to define the pattern in the outer surface of the TBP roller 10. The patterned dry film photoresist layer 20 serves as a mask. Therefore, contamination of the patterned roller 100 can be avoided. The first pattern 50 is transferred to the TBP roller 10 and the patterned roller 100 having a second pattern 70 is obtained. The second pattern 70 corresponds to the first pattern 50. The sandblasting machine 60 may be a dry sandblasting machine or a liquid sandblasting machine. The dry sandblasting machine may be a dry suction sandblasting machine, or other suitable dry sandblasting machines.

After sandblasting, the TBP roller 10 may be cleaned using a dry ice cleaning apparatus. The dry ice can strike against and remove leftover sandblasting materials on the TBP roller 10 and then evaporate. Therefore, no cleaning substance is left on the TBP roller 10.

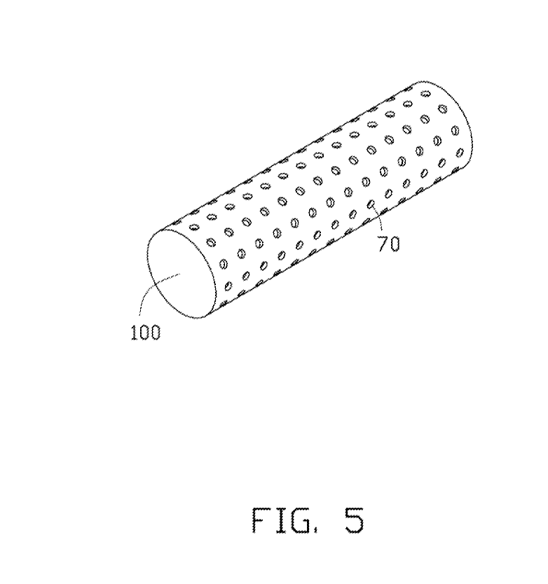

Referring to FIG. 5, the patterned roller 100 has the second pattern 70. The pattern roller 100 may be further cleaned using a liquid flow or an air flow process. Even if a copper TBP roller 10 is used, an electroplating process can be omitted.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for making a patterned roller, comprising:
forming a dry film photoresist layer on an outer surface of a to-be-patterned roller;
exposing the dry film photoresist layer to an exposure machine using a photomask;
developing the dry film photoresist layer to expose a plurality of portions of the outer surface of the to-be-patterned roller;
sandblasting the exposed portions of the outer surface of the to-be-patterned roller to define a pattern in the outer surface of the to-be-patterned roller; and
removing the remaining dry film photoresist layer to obtain a patterned roller.

2. The method of claim 1, further comprising cleaning the to-be-patterned roller using a dry ice cleaning apparatus after sandblasting.

3. The method of claim 1, further comprising cleaning the to-be-patterned roller using a liquid flow or an air flow after removing the remaining dry film photoresist layer.

4. The method of claim 1, wherein the sandblasting step is performed using a dry sandblasting machine or a liquid sandblasting machine.

5. A method for making a patterned roller, comprising:
providing a dry film photoresist layer;
rolling up the dry film photoresist layer around a cylindrical core;
exposing the dry film photoresist layer using a mask;
developing the dry film photoresist layer to define a pattern in the dry film photoresist layer with a plurality of portions of the cylindrical core being exposed;
sandblasting the exposed portions of the cylindrical core to define a pattern in the outer surface of the cylindrical core; and
removing the remaining dry film photoresist layer to obtain a patterned roller.
